(19) United States
(12) Patent Application Publication
(10) Pub. No.: US 2025/0118712 A1
(43) Pub. Date: Apr. 10, 2025

(54) LIGHT EMITTING PANEL

(71) Applicant: AUO Corporation, Hsin-Chu (TW)

(72) Inventors: JHONG-YUAN WANG, Hsin-Chu (TW); SHANG-CHIANG LIN, Hsin-Chu (TW); YA-LING HSU, Hsin-Chu (TW)

(21) Appl. No.: 18/764,395

(22) Filed: Jul. 5, 2024

(30) Foreign Application Priority Data
Oct. 6, 2023 (TW) 112138598

(51) Int. Cl. H01L 25/075; H01L 33/56; H01L 33/60

(52) U.S. Cl. CPC H01L 25/0753; H10H 20/854; H10H 20/856

(57) ABSTRACT

A light emitting panel includes: a substrate, a plurality of light emitting units arranged on the substrate, a diffuse reflective layer provided on the substrate and defining a plurality of openings, the light emitting units respectively positioned corresponding to the openings, and an encapsulating adhesive layer covering the light emitting units, the diffuse reflective layer and the openings on the substrate. In the light emitting panel, the vertical thickness of the encapsulating adhesive layer on the diffuse reflective layer is greater than 40 μm.

### CROSS-REFERENCE TO RELATED APPLICATION

This application claims the priority benefit of Taiwan application serial no. 112138598 filed on Oct. 6, 2023. The entirety of the above-mentioned patent application is hereby incorporated by reference herein and made a part of this specification.

### BACKGROUND

### 1. Technical Field

The present disclosure relates to a light emitting panel with a light emitting unit. Particularly, the present disclosure relates to a light emitting panel with a diffuse reflective layer surround the light emitting unit.

### 2. Related Art

In recent years, light emitting panels consisting of a plurality of light emitting units are widely used as light source components of display devices or light emitting devices. Based on the above, the luminous efficiency of the light emitting panel is affected by factors such as the layout, light emission characteristics, refractive index, reflectivity, size, etc. of the light emitting unit and other components in the light emitting panel. For example, factors such as the wide-angle light emission characteristics of the light emitting unit, the difference in refractive index between the encapsulant and the environment, and the reduction in size of the light emitting unit may make it more difficult for the light emitting panel to effectively emit light at a forward angle. Therefore, it is necessary to develop a structure that can improve the light emission efficiency for this type of light emitting panel.

### SUMMARY

In order to solve the above problems, an embodiment of the present invention provides a light emitting panel, which comprises: a substrate, a plurality of light emitting units arranged on the substrate, a diffuse reflective layer arranged on the substrate and defining a plurality of openings, the light emitting units respectively arranged corresponding to the openings, and an encapsulating adhesive layer covering the light emitting units, the diffuse reflective layer and the openings on the substrate, wherein a vertical thickness of the encapsulating adhesive layer on the diffuse reflective layer is greater than 40 μm.

Compared to the prior art, the light emitting panel according to various embodiments of the present disclosure can increase the probability that light is further diffusely reflected by the diffuse reflective layer, and can increase the probability that light from various angles will emit from the luminous panel at a positive angle. With reference to the above, the structure of the light emitting panel provided according to various embodiments of the present disclosure can further improve the overall light emission efficiency of the light emitting panel, and can be applied as various light source components.

### BRIEF DESCRIPTION OF THE DRAWINGS

FIG. 1 is a schematic three-dimensional view of a light emitting panel with a plurality of light emitting units according to an embodiment of the present disclosure.

FIG. 2 is a schematic cross-sectional view of the light emitting panel taken along the X-X′ section line of FIG. 1 according to an embodiment of the present disclosure.

FIG. 3 is a schematic view of the light emitting panel of FIG. 2 using a diffuse reflective layer to diffuse and reflect light according to an embodiment of the present disclosure.

FIG. 4 is a schematic cross-sectional view of a light emitting panel according to another embodiment of the present disclosure.

FIG. 5 and FIG. 6 are schematic enlarged cross-sectional views of the block Z of FIG. 4 according to different embodiments of the present disclosure.

FIG. 7 is a schematic view of the light emitting panel of FIG. 4 using a diffuse reflective layer to diffuse and reflect light according to an embodiment of the present disclosure.

FIG. 8 is a schematic cross-sectional view of a light emitting panel according to another embodiment of the present disclosure.

FIG. 9 is a schematic enlarged cross-sectional view of the block Z′ of FIG. 8 according to an embodiment of the present disclosure.

FIG. 10 is a schematic top view of the block Z″ of FIG. 8 according to an embodiment of the present disclosure.

FIG. 11 is a schematic cross-sectional view of a light emitting panel according to another embodiment of the present disclosure.

FIG. 12 is a schematic view of the light emitting panel of FIG. 11, which recovers possible lost light through a reflective layer according to an embodiment of the present disclosure.

FIG. 13 is a schematic cross-sectional view of a light emitting panel according to another embodiment of the present disclosure.

FIG. 14 is a schematic enlarged cross-sectional view of the block V of FIG. 13 according to an embodiment of the present disclosure.

FIG. 15 is a schematic cross-sectional view of a light emitting panel according to another embodiment of the present disclosure.

FIG. 16 is a bar chart showing the actual light emission efficiency of the structure of the light emitting panel under different size configurations according to an embodiment of the present disclosure.

FIG. 17 is a bar chart showing the actual light emission efficiency of the structure of the light emitting panel under different size configurations according to another embodiment of the present disclosure.

### DETAILED DESCRIPTION

Various embodiments will be described below, and those of ordinary skill in the art can easily understand the spirits and principles of the present disclosure referring to this specification accompanied by the drawings. However, although some particular embodiments will be specifically illustrated herein, these embodiments are only exemplary, and are not to be regarded as limiting or exhaustive in all respects. Therefore, for those of ordinary skill in the art, various changes and modifications to the present disclosure should be obvious and can be easily achieved without departing from the spirits and principles of the present disclosure.

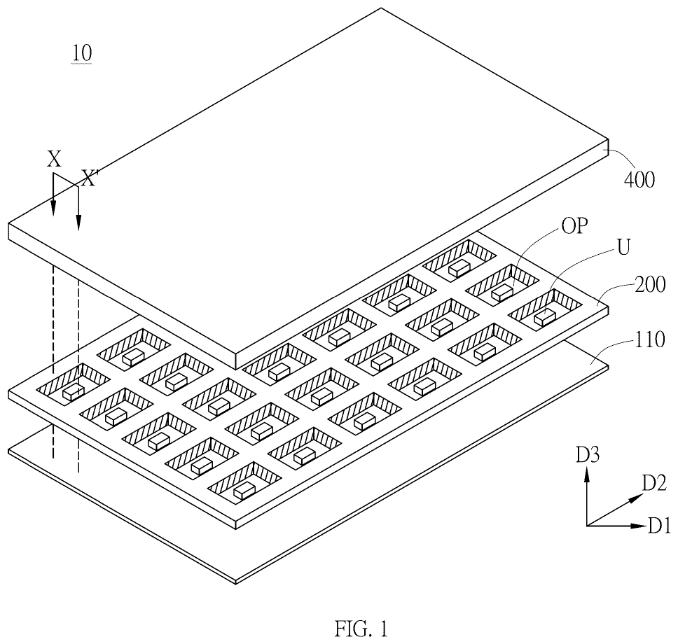

Referring to FIG. 1, a light emitting panel 10 according to an embodiment of the present disclosure includes: a substrate 110, a plurality of light emitting units U arranged on the substrate 110, a diffuse reflective layer 200 disposed on the substrate 110 and defining a plurality of openings OP, and an encapsulating adhesive layer 400 covering the light emitting units U, the diffuse reflective layer 200 and the openings OP on the substrate 110.

As shown in FIG. 1, the light emitting units U can be disposed on the substrate 110 corresponding to the openings OP respectively. With reference to this structure, each light emitting unit U may be at least partially surrounded by the diffuse reflective layer 200 along a first direction D1 and/or a second direction D2. In addition to covering the light emitting units U, the diffuse reflective layer 200 and the openings OP along a third direction D3, the encapsulating adhesive layer 400 is further filled in the openings OP, so that the individual light emitting units U and the diffuse reflective layer 200 can be at least partially embedded in the encapsulating adhesive layer 400.

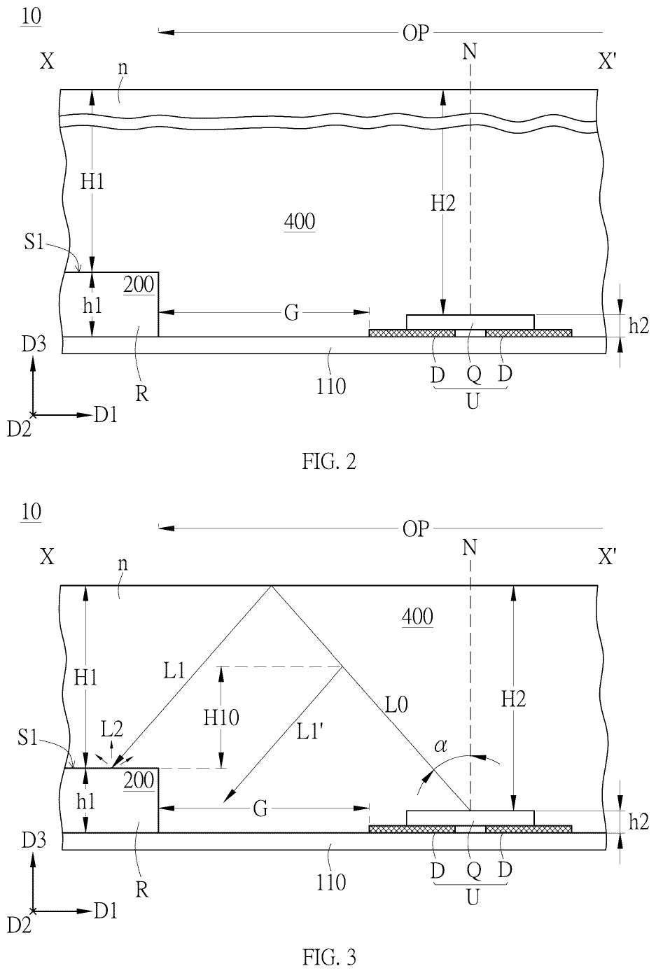

With further reference to the schematic cross-sectional view of FIG. 2 taken along the cross-section line X-X′ of FIG. 1, according to this embodiment, the light emitting unit U may, for example, include a light emitting source Q and a corresponding electronic component D. For example, the light emitting unit U may include a light emitting diode (LED), a mini light emitting diode (Mini LED), a micro light emitting diode (micro LED), a quantum dot light emitting diode (QD LED) or the like as the light emitting source Q, and the electronic component D may be electrode pads disposed on the substrate 110 and electrically connected to the light emitting source Q. However, these are only examples, and according to various embodiments of the present disclosure, the structure and implements of the light emitting unit U can have various changes, and the light emitting unit U can be composed of various units that can achieve light emission.

According to some embodiments, the diffuse reflective layer 200 disposed around the light emitting unit U can be any suitable structure capable of achieving diffuse reflection. Specifically, in order to achieve the diffuse reflection, the reflectance R of the diffuse reflective layer 200 in a specular component excluded (SCE) mode may be less than or equal to 100% and greater than or equal to 50%. For example, the reflectance R of the diffuse reflective layer 200 in the SCE mode may be greater than or equal to 80%. Thereby, when light is incident on the diffuse reflective layer 200, the diffuse reflective layer 200 can reflect the light in various wide-angle ranges other than the specular angle, so that the light can be emitted to various angles.

According to some embodiments, depending on the material or structure of the diffuse reflective layer 200 and the corresponding manufacturing process, the height h1 of the diffuse reflective layer 200 with reference to the substrate 110 may be between 1 μm and 25 μm. According to an embodiment, depending on the configuration or structure of the light emitting unit U and the corresponding manufacturing process, the light emitting unit U may have a height h2 with reference to the substrate 110. In this case, with respect to the height h2, if the height h1 becomes larger, light emitted from the light emitting unit U and possibly transmitted in the encapsulating adhesive layer 400 will be less able to reach a front surface S1 of the diffuse reflective layer 200, which faces toward the positive direction in the third direction D3. In addition, depending on the material or structure of the diffuse reflective layer 200 and the precision of corresponding manufacturing process, the light emitting unit U and the diffuse reflective layer 200 may be separated by a predetermined gap G. For example, the predetermined gap G may range from 1 μm˜70 μm. In this case, the larger the predetermined gap G is, the more difficult it is for the light emitted from the light emitting unit U and possibly transmitted in the encapsulating adhesive layer 400 to cross the predetermined gap G and reach the diffuse reflective layer 200.

According to some embodiments, as shown in FIG. 2, the diffuse reflective layer 200 may be made of white reflective ink dispersed with a plurality of diffusion particles, and the light emitting unit U may be, for example, the light emitting source Q of a micro light emitting diode. In this aspect, the height h1 of the diffuse reflective layer 200 may be 25 μm and greater than the height h2 of the light emitting unit U, and the predetermined gap G between the diffuse reflective layer 200 and the light emitting unit U may be 70 μm. Therefore, when the diffuse reflective layer 200 is made of, for example, the white reflective ink dispersed with a plurality of diffusion particles, and the light emitting unit U can be, for example, the light emitting source Q of the micro light emitting diode, at least part of the light may be difficult to reach the front surface S1 of the diffuse reflective layer 200 facing toward the positive direction in the third direction D3, or there may be at least part of the light falling within the predetermined gap G, so that at least part of the light may be lost and cannot be diffusely reflected.

Referring to FIG. 2 and FIG. 3, according to this embodiment, in the light emitting panel 10, in order to make the light emitted from the light emitting unit U easier reach the diffuse reflective layer 200 and be diffusely reflected by the front surface S1 of the diffuse reflective layer 200 facing toward the positive direction in the third direction D3, the vertical thickness H1 of the encapsulating adhesive layer 400 on the diffuse reflective layer 200 can be at least greater than 40 μm, and the vertical thickness H2 of the encapsulating adhesive layer 400 on the light emitting unit U can be modified corresponding to the vertical thickness H1.

Specifically, as shown in FIG. 3, since the encapsulating adhesive layer 400 may have a refractive index n, when the light emitting unit U emits light L0 at an angle α greater than a specific angle relative to a normal N, the light LO is prone to total reflection at the interface between the encapsulating adhesive layer 400 and the outside environment and cannot exit from the light emitting panel 10. For example, the refractive index of the encapsulating adhesive layer 400 can be 1.58; the outside environment is the atmospheric environment, and the refractive index thereof can be 1. In this case, when the emission angle α is too large, total reflection of light is likely to occur at the interface between the encapsulating adhesive layer 400 and the outside environment. However, the refractive index of the encapsulating adhesive layer 400 and the refractive index of the outside environment described here are only examples, and the situations in which total reflection may occur according to various embodiments of the present disclosure are not limited thereto. When total reflection occurs, if a vertical thickness H10 on the diffuse reflective layer 200 is less than 40 μm, a light L1′ resulted from the total reflection of light L0 can easily fall within the above-mentioned predetermined gap G, and therefore the light L1′ will no longer be diffusely reflected and emitted out. In contrast, if the vertical thickness H1 on the diffuse reflective layer 200 is greater than 40 μm, the light L1 resulted from the total reflection of the light L0 can more easily cross the above-mentioned predetermined gap G and reach the front surface S1 of the diffuse reflective layer 200 and be diffused and reflected again at a wide-angle. Due to the angle change of the diffusely reflected light L2 (for example, it is no longer the original angle that is easy to be totally reflected at the interface), the probability of the light L2 emitting from the light emitting panel 10 can be further increased. Therefore, the light emitting panel 10 of this embodiment can recover the light that was originally easily lost and then diffuse and reflect the recovered light, thereby improving the light emission efficiency of the overall light emitting panel 10.

With reference to the above, the light emitting panel 10 provided according to this embodiment has higher light emission efficiency and can be applied as various light source components. For example, it can be used as a backlight panel of an electronic device, or as a light source component for the luminous panel of a display device or a light emitting device. According to various embodiments of the present disclosure, the applicable applications are not limited to the above specific examples.

According to some embodiments, depending on the material, structure or relative size of each component in the light emitting panel 10, the vertical thickness H1 of the encapsulating adhesive layer 400 on the diffuse reflective layer 200 may be greater than or equal to 100 μm to obtain the better light emission efficiency. Alternatively, depending on the material, structure or relative size of each component in the light emitting panel 10, the vertical thickness H1 of the encapsulating adhesive layer 400 on the diffuse reflective layer 200 can be greater than or equal to 150 μm to obtain the better light emission efficiency.

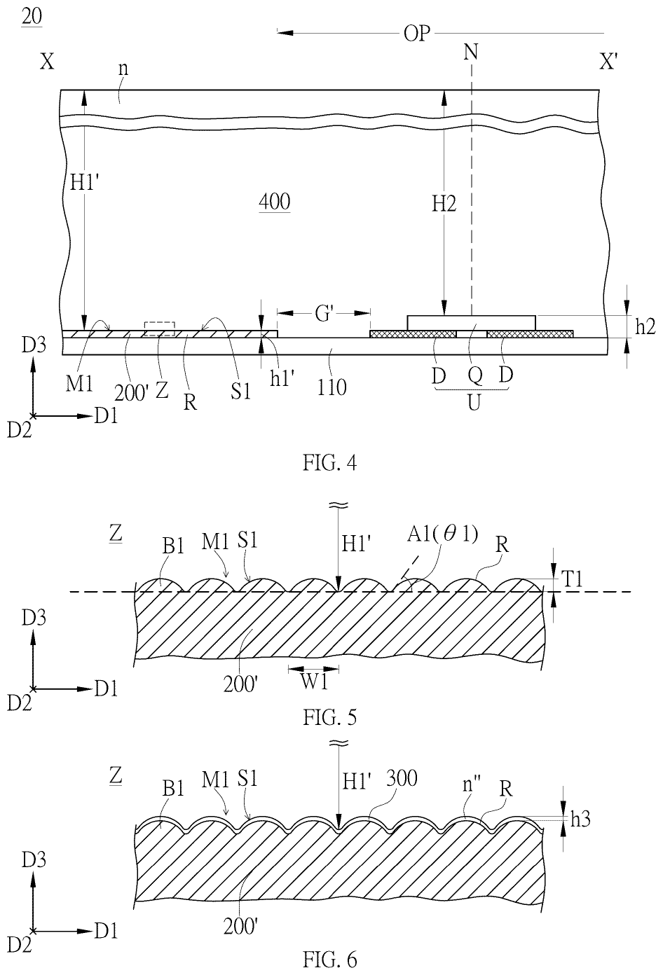

Referring to FIG. 4, according to another embodiment of a light emitting panel 20 of the present disclosure, a diffuse reflective layer 200′ can achieve diffuse reflection by disposing the first microstructure M1 on the front surface S1. Specifically, refer to FIG. 4 and FIG. 5, which is an enlarged schematic view of the block Z of FIG. 4. According to this embodiment, the diffuse reflective layer 200′ can be made of materials with or without diffuse reflection properties to achieve the diffuse reflection function by arranging the first microstructure M1 on the front surface S1, wherein first microstructure M1 can include a plurality of first bumps B1.

According to this embodiment, the front surface S1 of the diffuse reflective layer 200′ facing away from the substrate 110 may have the first microstructure M1 including a plurality of first bumps B1. Therefore, the diffuse reflective layer 200′ may not be limited to being made of diffuse reflective materials such as white reflective ink with a plurality of diffusion particles. For example, the diffuse reflective layer 200′ can be made of metals such as aluminum, silver, nickel or the like that have high reflectivity but no diffuse reflection property itself. More specifically, the diffuse reflective layer 200′ can be made of a material that has high or low reflectance R in the SCE mode, and through the arrangement of the first microstructure M1, the overall diffuse reflective layer 200′ may have a reflectance R greater than or equal to 50% or even 80% in the SCE mode.

When the first microstructure M1 is used to realize the diffuse reflection function, the diffuse reflective layer 200′ can be made of more types of materials, and according to some embodiments, can therefore have a smaller height h1′ and/or a smaller predetermined gap G′. For example, when the diffuse reflective layer 200′ is made of aluminum with a high Specular Component Included (SCI) but the low Specular Component Excluded (SCE), since the manufacturing process using aluminum can have higher precision, the height h1′ of the corresponding diffuse reflective layer 200′ may be smaller than the height h2 of the light emitting unit U, and the predetermined gap G′ can also be further reduced. For example, the height h1′ of the diffuse reflective layer 200′ made of aluminum with reference to the substrate 110 can be less than 3 μm, such as 1.7 μm, and the predetermined gap G′ can be less than 25 μm, such as 20 μm. Therefore, when the height h2 of the light emitting unit U is fixed, it is easier to reduce the space of the height h1′ and increase the vertical thickness H1′ to at least greater than 40 μm, and the light falling within the range of the predetermined gap G′ can be reduced or prevented, thereby significantly increasing the amount of light that can reach the front surface S1 of the diffuse reflective layer 200′.

Referring to FIG. 5, according to some embodiments, in order to achieve the desired diffuse reflection, a predetermined angle θ1 for the base angle A1 of the first bumps B1 may be between 7 degrees and 50 degrees. Further, according to some embodiments, the first bumps B1 may respectively have a first bump thickness T1 and a first bump width W1. The first bump thickness T1 may be, for example, a thickness from a trough to a peak with respect to the first bump B1, and the first bump width W1 may be, for example, a width from trough to trough with respect to the first bump B1, wherein tan(θ1)=2(T1)/(W1). Within the range of the predetermined angle θ1 for the base angle A1, the first microstructure M1 composed of a plurality of first bumps B1 can have the desired diffuse reflection. For example, the reflectance R in the SCE mode is greater than or equal to 50% or even 80%.

According to some embodiments, the first bump thickness T1 may range from 0 to 1 μm, and the first bump width W1 may range from 0 to 10 μm, but not limited thereto.

In addition, referring to FIG. 4 and FIG. 6, in order to protect the above-mentioned first microstructure M1, according to some embodiments of the present disclosure, the light emitting panel 20 may further include a protective layer 300 laid on the first microstructure M1. In order to reduce or avoid affecting the diffuse reflection achieved by the first microstructure M1, the thickness h3 of the protective layer 300 can be between 1000 Å and 2000 Å, which is much smaller than the height h1′ of the overall diffuse reflective layer 200′. In addition, the refractive index n″ of the protective layer 300 can be within the range of ±0.1 of the refractive index n of the encapsulating adhesive layer 400 (i.e., n±0.1), thereby reducing or preventing refraction of light at the interface between the protective layer 300 and the encapsulating adhesive layer 400 when the light is reflected from the first microstructure M1. According to some embodiments, the protective layer 300 may be formed of, for example, polyvinyl chloride resin (PV), but not limited thereto.

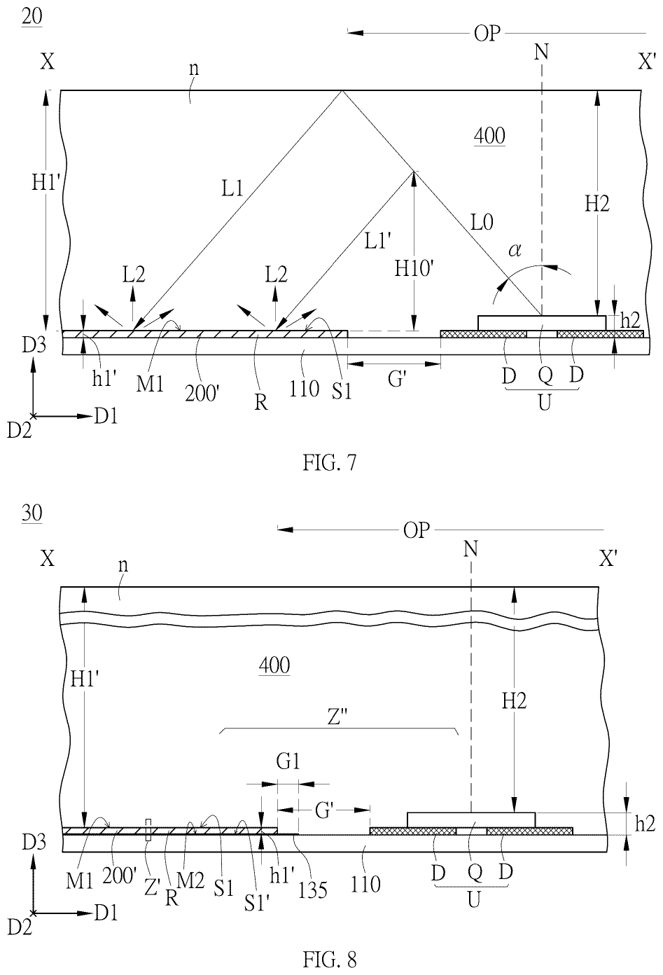

Refer to FIG. 7, which shows the diffuse reflection of light by the light emitting panel 20 of FIG. 4, and details similar or identical to those described above with reference to FIG. 3 will be omitted and will not be described again. Based on the above, when the light emitting unit U emits light L0 at an angle a greater than a specific angle with respect to the normal N, the light L0 is prone to total reflection at the interface between the encapsulating adhesive layer 400 and the outside environment. However, according to this embodiment, since the predetermined gap G′ is reduced, the diffuse reflective layer 200′ can be further extended along the first direction D1 close to the light-emitting unit U, and therefore, the front surface S1 can correspondingly receive and diffusely reflect more total reflected light L1 or L1′. Therefore, according to some embodiments, when reducing the predetermined gap G′ and reducing the height h1′ of the diffuse reflective layer 200′, even if a vertical thickness H10′ relatively smaller than the vertical thickness H1′ is used, the light L1′ resulted from the total reflection of light L0 can also easily cross the above-mentioned predetermined gap G′ and reach the front surface S1 of the diffuse reflective layer 200′ to be diffused and reflected again at a wide-angle. Due to the angle change of the diffusely reflected light L2 (for example, it is no longer the original angle that is easy to be totally reflected at the interface), the probability of the light L2 emitting from the light emitting panel 20 can be further increased. Therefore, the light emitting panel 20 of this embodiment can recover the light that was originally easily lost and then diffuse and reflect the recovered light, thereby improving the light emission efficiency of the overall light emitting panel 20.

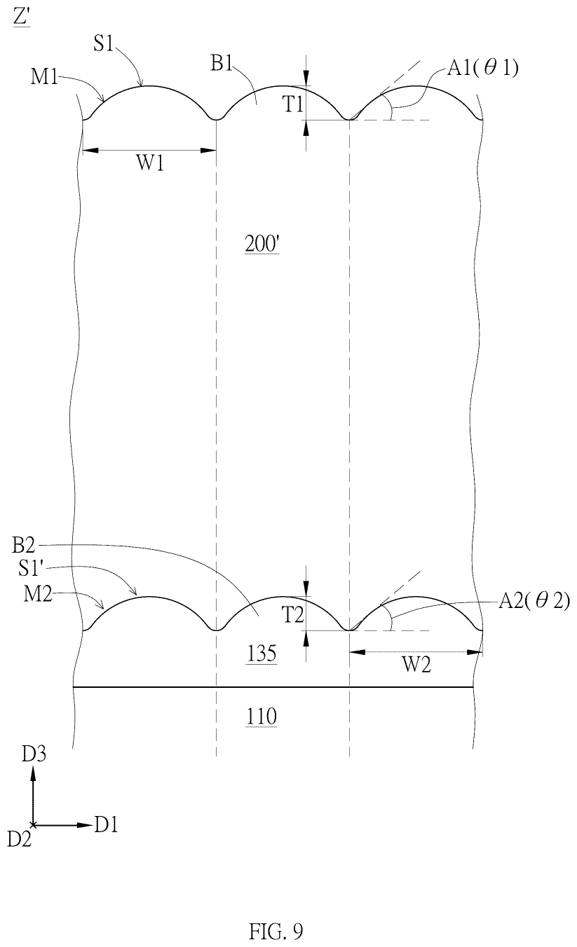

In addition, the first bumps B1 of the above-mentioned first microstructure M1 can be formed by directly laying a metal layer on the substrate 110, and then further etching the metal layer to form a topography. However, the present disclosure is not limited thereto, and the topography of the first bumps B1 of the first microstructure M1 may be formed in various ways according to other embodiments. For example, referring to a light emitting panel 30 shown in FIG. 8, before forming the light emitting unit U and the diffuse reflective layer 200′, an insulating microstructure layer 135 can be formed on the substrate 110. In the light emitting panel 30, the insulating microstructure layer 135 can be disposed between the diffuse reflective layer 200′ and the substrate 110 corresponding to the diffuse reflective layer 200′. Referring to FIG. 8 and FIG. 9, which is an enlarged schematic view of the block Z′ in FIG. 8, a front surface S1′ of the insulating microstructure layer 135 facing away from the substrate 110 may have a second microstructure M2 including a plurality of second bumps B2. When the diffuse reflective layer 200′ is laid on the insulating microstructure layer 135, the first microstructure M1 can be naturally formed according to the outline of the insulating microstructure layer 135, and thus can correspond to the respective second bumps B2 and form the first bumps B1. Therefore, within the vertical projection of the first bumps B1 on the insulating microstructure layer 135, the positions of the first bumps B1 and the second bumps B2 may correspond to each other.

According to some embodiments, the second bump B2 may be the same as or similar to the first bump B1. For example, a second bump thickness T2 may be the same as or similar to the first bump thickness T1, and a second bump width W2 may be the same as or similar to the first bump width W1. In addition, an angle 02 of a base angle A2 of the second bump B2 may be the same as or similar to the angle 01 of the base angle A1 of the first bump B1. Thereby, when the diffuse reflective layer 200′ is laid on the second bumps B2, the first bumps B1 can be formed corresponding to the outline of the second microstructure M2. However, the above are only examples, and according to other embodiments of the present disclosure, as long as the expected first bumps B1 can be formed when the diffuse reflective layer 200′ is laid on the second bumps B2, and the vertical projection of the first bumps B1 corresponds to the position of the second bumps B2, the second bump B2 may be different in shape or size from the first bump B1. For example, the second bump B2 may be formed at a larger base angle A2 with the angle θ2, or may have a higher second bump thickness T2, etc., so that the diffuse reflective layer 200′ may become smoother when the diffuse reflective layer 200′ is laid. In this case, the predetermined first bumps B1 can still be formed as expected. However, the above are only examples, and other embodiments according to the present disclosure are not limited thereto.

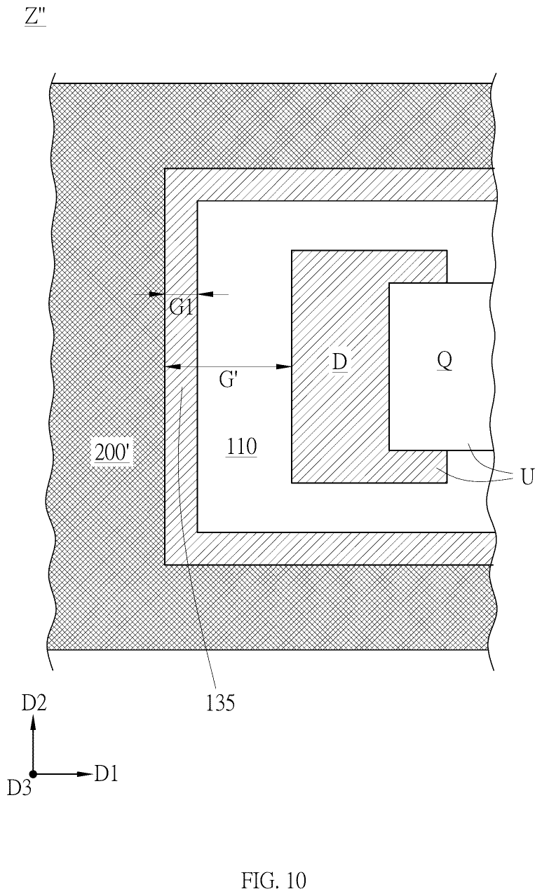

Further, according to some embodiments, the area of the insulating microstructure layer 135 may be larger than the area of the diffuse reflective layer 200′. Referring to FIG, 8 and FIG. 10, which is a schematic top view of the block Z″ in FIG. 8, the insulating microstructure layer 135 may, for example, protrude outward relative to the diffuse reflective layer 200′ by a protruding gap G1. For example, along the first direction D1, the insulating microstructure layer 135 may protrude relative to the diffuse reflective layer 200′ toward the light emitting unit U into the predetermined gap G′. Therefore, the chance of failure in molding the first bump B1 at the edge diffuse reflective layer 200′ along the outline of the second bump B2, for example, due to tolerance differences or deviation defects in alignment, can be reduced or avoided. By expanding the insulating microstructure layer 135 relative to the diffuse reflective layer 200′, the edge of the diffuse reflective layer 200′ can be shaped more accurately corresponding to the second microstructure M2.

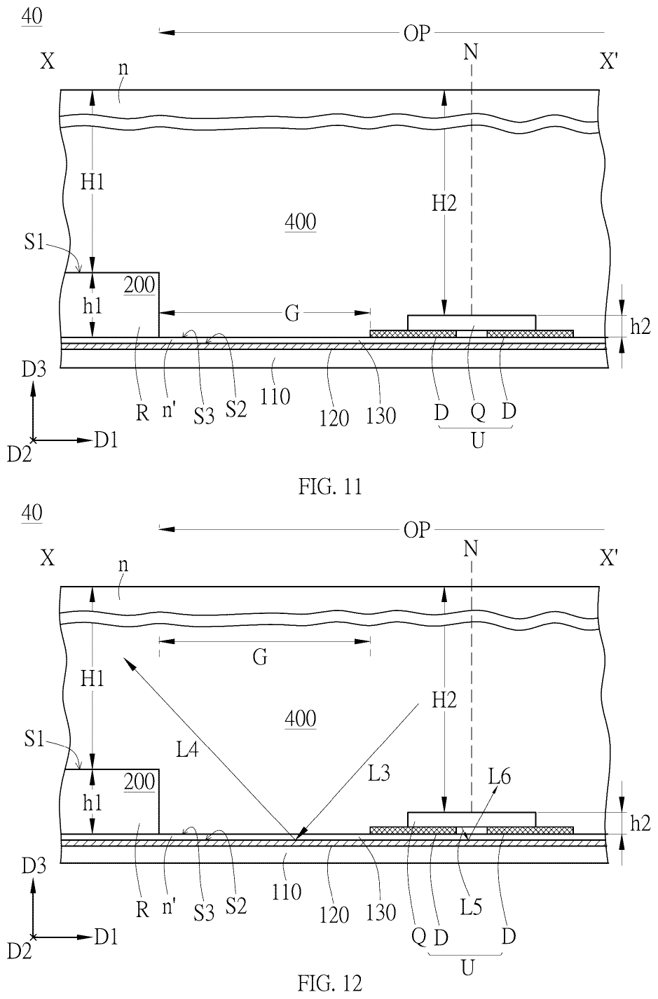

Next, referring to FIG. 11, a light emitting panel 40 according to another embodiment of the present disclosure may have the same or similar structure to the light emitting panel 10 shown in FIG. 2, and the difference is that the light emitting panel 40 may further include a reflective layer 120 and an insulating layer 130 sequentially stacked on the substrate 110. The reflective layer 120 may be made of metals with high reflectance, such as aluminum, silver, nickel, etc. The insulating layer 130 can be made of materials with insulating properties such as polyurethane (UHA), polyimide (PI), polycarbonate (PC), etc., and have high reflectance and insulating properties, but other embodiments according to the present disclosure may not be limited thereto. The reflective layer 120 and the insulating layer 130 can be formed on the substrate 110 before disposing the light emitting unit U and the diffuse reflective layer 200. And finally, the reflective layer 120 and the insulating layer 130 can be correspondingly disposed between the substrate 110 and the light emitting units U or between the substrate 110 and the diffuse reflective layer 200.

When the reflective layer 120 and the insulating layer 130 are provided, the height h1 of the diffuse reflective layer 200 can be calculated with reference to the insulating layer 130, and the height h1 can be between 1 μm and 25 μm. Similarly, the height h2 of the light emitting unit U can be calculated with reference to the insulating layer 130, and this can be deduced accordingly to other aspects in this specification in which the reflective layer 120 and the insulating layer 130 are provided (for example, corresponding to height h1′ of the diffuse reflective layer 200′), and will not be described again hereafter.

With reference to the above, according to the embodiment shown in FIG. 11, in order to further increase the recovery rate of the light falling within the predetermined gap G, the reflective layer 120 can be disposed on the entire substrate 110, so that a front surface S2 of the reflective layer 120 can be used for reflecting light. Furthermore, in order to reduce and avoid the possibility that the reflective layer 120 may unexpectedly interact with the light emitting unit U, for example, the reflective layer 120 made of metal may unexpectedly affect the electrical characteristics or electrical conduction of the electronic component D of the light emitting unit U, an insulating layer 130 is then provided on the reflective layer 120. The refractive index n′ of the insulating layer 130 can be within the range of ±0.1 of the refractive index n of the encapsulating adhesive layer 400 (i.e., n±0.1). Therefore, according to this embodiment, changes in the insulating layer 130 that affect the reflective ability or reflective characteristics of the reflective layer 120 can be reduced or avoided.

As mentioned above, referring to FIG. 12, when a light L3 falls in the predetermined gap G of the light emitting panel 40, the front surface S2 of the reflective layer 120 can, for example, reflect the light L3 into a light LA and guide it closer to the diffuse reflective layer 200. When there is a sufficient vertical thickness H1, the light L4 is completely reflected at the interface between the encapsulating adhesive layer 400 and the outside environment. After reflection, it is close to the diffuse reflective layer 200 and has a chance to reach the front surface S1 of the diffuse reflective layer 200, and is diffusely reflected accordingly. Therefore, according to this embodiment, the light in the predetermined gap G can be further recovered, and the probability of the light emitting from the light emitting panel 40 is increased.

In addition, referring to FIG. 12, according to this embodiment, when the light emitting source Q of the light emitting unit U is a wide-angle light source, a light L5 emitted toward the substrate 110 can also be reflected by the front surface S2 of the reflective layer 120 as a light L6 emitted away from the substrate 110. Therefore, according to this embodiment, the light that is emitted toward the back of the light emitting unit U can be further recovered, and the probability of the light emitting from the light emitting panel 40 is increased. With reference to the above, by recovering the light falling in the predetermined gap G and/or the light emitted toward the back of the light emitting unit U, according to this embodiment, the light emission efficiency of the overall light emitting panel 40 can be further improved.

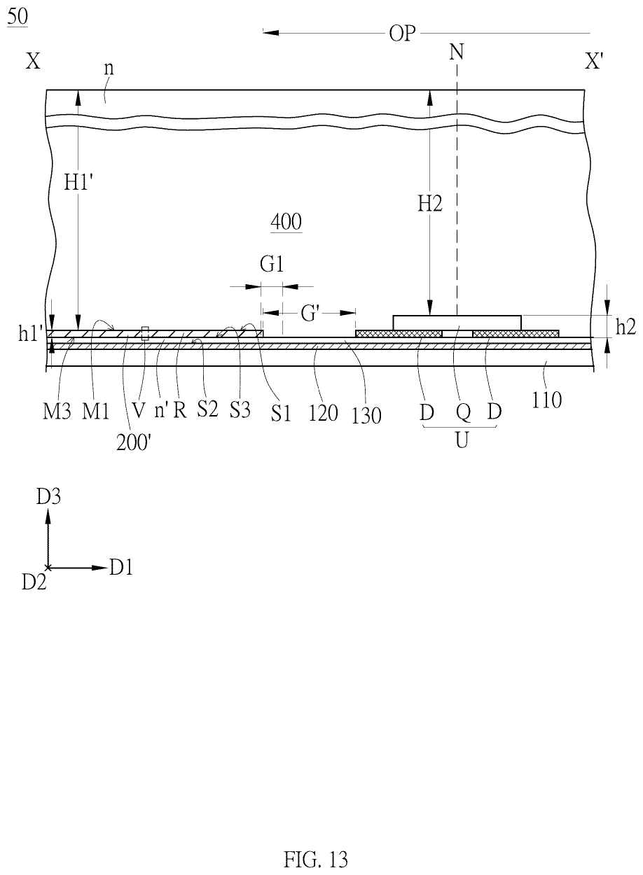

Further, referring to FIG. 13, a light emitting panel 50 according to another embodiment of the present disclosure may have the same or similar structure to the light emitting panel 20 shown in FIG. 4, and the difference is that the light emitting panel 50 may further include the reflective layer 120 and the insulating layer 130 sequentially stacked on the substrate 110 similarly to the above. With reference to the above, according to this embodiment, similar to the aspect shown above with reference to FIG. 12, the light emission efficiency of the overall light emitting panel 50 can be improved by recovering the light falling in the predetermined gap G′ and/or the light emitted toward the back of the light emitting unit U.

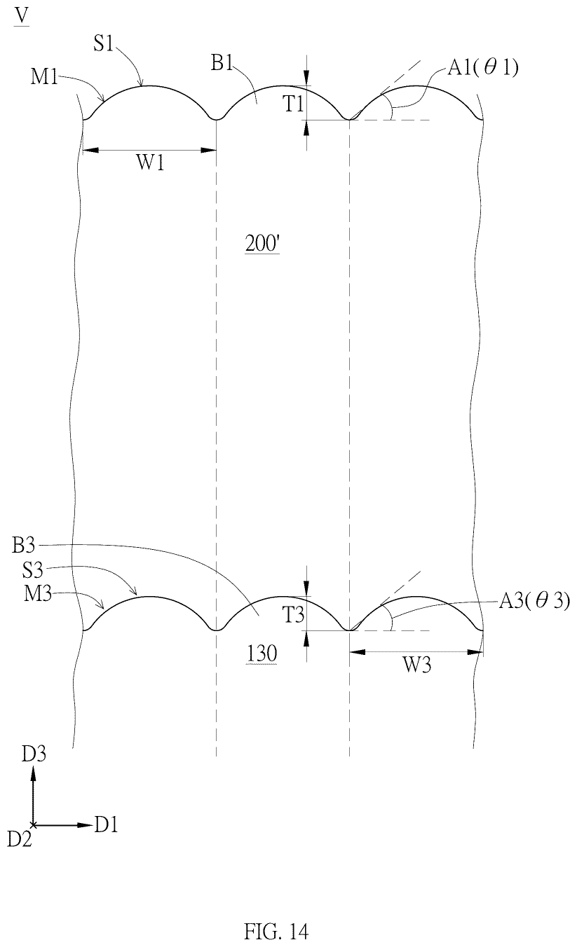

In addition, referring to FIG. 13 and FIG. 14 which is an enlarged schematic view of the block V in FIG. 13, according to this embodiment, the first microstructure M1 can be correspondingly formed based on the insulating layer 130. Specifically, the insulating layer 130 at least corresponds to the projection area of the diffuse reflective layer 200′, or in addition to corresponding to the projection area of the diffuse reflective layer 200′, the insulating layer 130 further extends by a protruding gap G1, and a third microstructure M3 is locally formed within the range of the insulating layer 130. Following the above, a front surface S3 of the insulating layer 130 facing away from the substrate 110 may have the third microstructure M3 including a plurality of third bumps B3, and the first microstructure M1 composed of the first bumps B1 of the diffuse reflective layer 200′ may be formed corresponding to the outline of the front surface S3 of the insulating layer 130. Therefore, within the range where the first bumps B1 are vertically projected on the insulating layer 130, the positions of the first bumps B1 and the third bumps B3 may correspond to each other.

According to some embodiments, the third bump B3 may be the same as or similar to the first bump B1. For example, a third bump thickness T3 may be the same as or similar to the first bump thickness T1, and a third bump width W3 may be the same as or similar to the first bump width W1. In addition, an angle θ3 of a base angle A3 of the third bump B3 may be the same as or similar to the angle θ1 of the base angle A1 of the first bump B1. Thereby, when the diffuse reflective layer 200′ is laid on the third bumps B3, the first bumps B1 can be formed corresponding to the outline of the third microstructure M3. However, the above are only examples, and according to other embodiments of the present disclosure, as long as the expected first bumps B1 can be formed when the diffuse reflective layer 200′ is laid on the third bumps B3, and the vertical projection of the first bump B1 corresponds to the position of the third bump B3, the shape or size of the third bump B3 may be different from the first bump B1. For example, the third bump B3 may be formed at a larger base angle A3 with an angle θ3, or may have a higher third bump thickness T3, etc., so that the diffuse reflective layer 200′ may become smoother when the diffuse reflective layer 200′ is laid. In this case, the predetermined first bump B1 can still be formed as expected. However, the above are only examples, and other embodiments according to the present disclosure are not limited thereto.

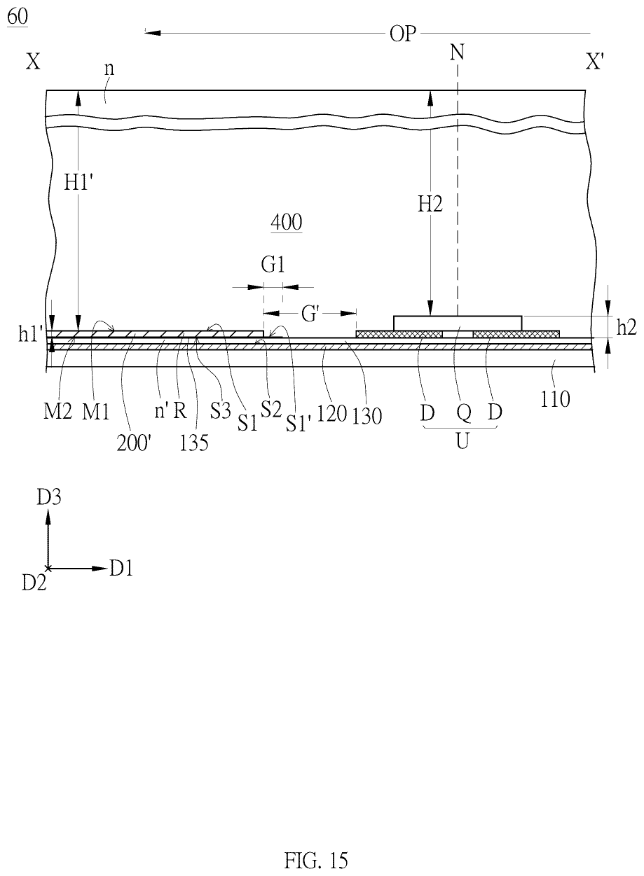

In addition, with further reference to FIG. 15, even when the reflective layer 120 and the insulating layer 130 are provided, the first bump B1 may not be formed based on the insulating layer 130. According to a light emitting panel 60 shown in FIG. 15, the difference compared to the above-mentioned light emitting panel 50 may be that the insulating microstructure layer 135 having a second microstructure M2 is sandwiched between the diffuse reflective layer 200′ and the insulating layer 130, and the insulating layer 130 may not have a microstructure design. Thereby, the first microstructure M1 can be formed based on the profile of the insulating microstructure layer 135 instead of the insulating layer 130. The process of forming the first microstructure M1 based on the insulating microstructure layer 135 has been described in detail with reference to the above-mentioned FIGS. 8 to 10, and will not be described again here.

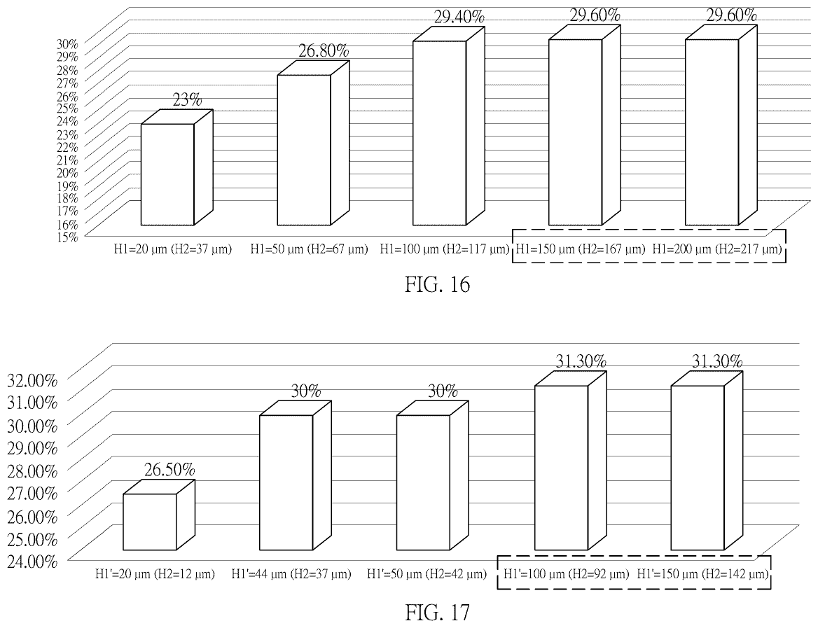

The experimental results of the actual light emission efficiency of the structure of the light emitting panel according to various embodiments of the present disclosure will be described below with reference to FIG. 16 and FIG. 17. Among them, the light emission efficiency shown on the vertical axis can be the proportion of light that can actually be emitted from the light emitting panel when the light emission of the light emitting unit itself is defined as 100%.

Referring to FIG. 16, based on a structure similar to the light emitting panel 40 shown in FIG. 11, the reflective layer 120 and the insulating layer 130 may be provided, and a white reflective ink dispersed with a plurality of diffusion particles may be used to form the diffuse reflective layer 200 accordingly. Under this structure, when the vertical thickness H1 of the encapsulating adhesive layer 400 on the diffuse reflective layer 200 becomes larger (wherein the vertical thickness H2 on the light emitting unit U also increases correspondingly), the light emission efficiency of the overall light emitting panel (vertical axis) can be correspondingly increased. Among them, when the diffuse reflective layer 200 is formed by using white reflective ink dispersed with a plurality of diffusion particles, and the vertical thickness H1 of the encapsulating adhesive layer 400 on the diffuse reflective layer 200 is greater than or equal to 150 μm, the light emission efficiency can relatively achieve 29.6%. Therefore, if considering thinning the volume of the overall light emitting panel, the vertical thickness H1 can be set correspondingly to approximately 150 μm to achieve higher light emission efficiency.

Similarly, referring to FIG. 17, based on a structure similar to the light emitting panel 50 shown in FIG. 13, a reflective layer 120 and an insulating layer 130 may be provided, and aluminum with the first microstructure M1 may be used accordingly to form diffuse reflective layer 200′. Under this structure, when the vertical thickness H1 of the encapsulating adhesive layer 400 on the diffuse reflective layer 200′ becomes larger (wherein the vertical thickness H1′ on the light emitting unit U also increases correspondingly), the light emission efficiency of the overall light emitting panel (vertical axis) can be correspondingly increased. Among them, when the diffuse reflective layer 200′ is formed by using aluminum with the first microstructure M1, and the vertical thickness H1′ of the encapsulating adhesive layer 400 on the diffuse reflective layer 200 is greater than or equal to 100 μm, the light emission efficiency can relatively achieve 31.30%. Therefore, if considering thinning the volume of the overall light emitting panel, the vertical thickness H1′ can be set correspondingly to approximately 100 μm to achieve higher light emission efficiency.

As shown in the experimental results of FIGS. 16 and 17, according to various embodiments of the present disclosure, when the vertical thickness H1/H1′ of the encapsulating adhesive layer disposed on the diffuse reflective layer meets the predetermined thickness, the light emitting panel can relatively realize higher light emission efficiency.

In summary, the light emitting panel according to various embodiments of the present disclosure can further recover light that is difficult to exit and guide the light to the diffuse reflective layer, thereby increasing the chance of the light being diffusely reflected and emitted out from the light emitting panel. Therefore, the light emitting panel according to various embodiments of the present disclosure can reduce or avoid the loss of light in the light emitting panel, thereby improving the light emission efficiency of the overall light emitting panel. With reference to above, the light emitting panel with higher light emission efficiency provided according to the embodiments can be used as various light source components, such as a backlight panel of an electronic device, or a light source component of a display device. According to various embodiments of the present disclosure, the applicable aspects are not limited to the specific examples in this disclosure.

The above description contains only some preferred embodiments of the present disclosure. Among them, the proportions and relative proportions of each component or part shown in the drawings may be exaggerated or changed for the purpose of clear display or convenience of explanation, and those with ordinary skill in the art should understand that they are not intended to be specific dimensional limitations. In addition, it should be noted that various changes and modifications can be made to the present disclosure without departing from the spirit and principles of the present disclosure. Those of ordinary skill in the art should understand that the present disclosure is defined by the appended claims, and under the spirit of the present disclosure, all possible replacements, combinations, modifications, diversions and other changes would not exceed the scope of the present disclosure defined by the appended claims.

What is claimed is:

1. A light emitting panel, comprising:
a substrate;
a plurality of light emitting units arranged on the substrate;
a diffuse reflective layer provided on the substrate and defining a plurality of openings, wherein the light emitting units are respectively positioned corresponding to the openings; and
an encapsulating adhesive layer covering the light emitting units, the diffuse reflective layer and the openings on the substrate, wherein a vertical thickness of the encapsulating adhesive layer on the diffuse reflective layer is greater than 40 μm.

2. The light emitting panel of claim 1, wherein the light emitting units respectively comprise micro light emitting diodes as a light source.

3. The light emitting panel of claim 1, wherein the light emitting units are separated from the diffuse reflective layer by a predetermined gap.

4. The light emitting panel of claim 3, wherein the predetermined gap is between 1 μm and 70 μm.

5. The light emitting panel of claim 4, wherein the predetermined gap is less than 25 μm.

6. The light emitting panel of claim 1, wherein a height of the diffuse reflective layer with reference to the substrate is between 1 μm and 25 μm.

7. The light emitting panel of claim 6, wherein the height of the diffuse reflective layer with reference to the substrate is less than 3 μm.

8. The light emitting panel of claim 1, wherein a reflectance of the diffuse reflective layer in a Specular Component Excluded (SCE) mode is less than or equal to 100% and greater than or equal to 50%.

9. The light emitting panel of claim 1, wherein a reflectance of the diffuse reflective layer in a Specular Component Excluded (SCE) mode is greater than or equal to 80%.

10. The light emitting panel of claim 1, wherein the diffuse reflective layer is made of white reflective ink dispersed with a plurality of diffusion particles.

11. The light emitting panel of claim 1, wherein a front surface of the diffuse reflective layer facing away from the substrate has a first microstructure including a plurality of first bumps.

12. The light emitting panel of claim 11, further comprising an insulating microstructure layer, wherein the insulating microstructure layer is disposed between the diffuse reflective layer and the substrate corresponding to the diffuse reflective layer, and wherein a front surface of the insulating microstructure layer facing away from the substrate has a second microstructure including a plurality of second bumps, and within a range of a vertical projection of the first bumps on the insulating microstructure layer, positions of the first bumps and the second bumps correspond to each other.

13. The light emitting panel of claim 11, wherein a predetermined angle (θ1) of a bottom angle of the first bumps is between 7 degrees and 50 degrees.

14. The light emitting panel of claim 13, wherein the first bumps have a first bump thickness (T1) and a first bump width (W1), and tan(θ1)=2(T1)/(W1).

15. The light emitting panel of claim 1, wherein the vertical thickness of the encapsulating adhesive layer on the diffuse reflective layer is greater than or equal to 100 μm.

16. The light emitting panel of claim 15, wherein the vertical thickness of the encapsulating adhesive layer on the diffuse reflective layer is greater than or equal to 150 μm.

17. The light emitting panel of claim 1, further comprising a reflective layer and an insulating layer sequentially stacked on the substrate, wherein the reflective layer and the insulating layer are disposed between the substrate and the light emitting units or between the substrate and the diffuse reflective layer.

18. The light emitting panel of claim 17, wherein a front surface of the diffuse reflective layer facing away from the substrate has a first microstructure including a plurality of first bumps, and a front surface of the insulating layer facing away from the substrate has a third microstructure including a plurality of third bumps, and wherein within a range of a vertical projection of the first bumps on the insulating layer, positions of the first bumps and the third bumps correspond to each other.

19. The light emitting panel of claim 17, wherein a refractive index of the insulating layer is within a range of ±0.1 of a refractive index of the encapsulating adhesive layer.

20. The light emitting panel of claim 1, wherein a front surface of the diffuse reflective layer facing away from the substrate has a first microstructure including a plurality of first bumps, and the light emitting panel further includes a protective layer laid on the first microstructure, and wherein a refractive index of the protective layer is within a range of ±0.1 of a refractive index of the encapsulating adhesive layer.

21. The light emitting panel of claim 20, wherein a thickness of the protective layer is between 1000 Å and 2000 Å.
